(19) United States
(12) Patent Application Publication
(10) Pub. No.: US 2005/0266163 A1
(43) Pub. Date: Dec. 1, 2005

(54) Extremely strain tolerant thermal protection coating and related method and apparatus thereof

(76) Inventors: David J. Wortman, Hamilton, OH (US); Haydn N.G. Wadley, Keswick, VA (US)

Correspondence Address: UNIVERSITY OF VIRGINIA PATENT FOUNDATION, 250 WEST MAIN STREET, SUITE 300, CHARLOTTESVILLE, VA, 22902, US

(21) Appl. No.: 10/533,993

(22) PCT Filed: Nov. 12, 2003
(86) PCT No.: PCT/US03/36035

§ 371 Date: May 5, 2005

Related U.S. Application Data
(60) Provisional application No. 60/425,524, filed on Nov. 12, 2002.

(51) Int. Cl. C23C 16/00; B44C 1/22

(52) U.S. Cl. 427/248.1; 118/723 VE; 118/720; 216/37; 427/402

(57) ABSTRACT

Method and Apparatus for efficiently applying coating systems to a surface that can survive the thermal gradient that is encountered in high temperature, high heat flux environments such as a rocket engine or like using vapor or cluster deposition process such as a directed vapor deposition (DVD) approach. Method and Apparatus provides electron or other energetic beam technique to evaporate and deposit compositionally and morphologically controlled bond coats at high rate while providing a highly strain tolerant thermal barrier coating that has an improved porosity morphology between columnar grains.

### CROSS-REFERENCE TO RELATED APPLICATIONS

The present invention claims priority from U.S. Provisional Application Ser. No. 60/425,524 filed Nov. 12, 2002, entitled “Extremely Strain Tolerant Thermal Protection Coating for Rocket Engines and Related Method thereof.” the entire disclosure of which is hereby incorporated by reference herein.

The present application is also related to International Application No. PCT/US03/23111, filed Jul. 24, 2003, entitled “Method and Apparatus for Dispersion Strengthened Bond Coats for Thermal Barrier Coatings,” of which is assigned to the present assignee and is hereby incorporated by reference herein in its entirety.

The present application is also related to International Application No. PCT/US02/28654, filed Sep. 10, 2002, entitled “Method and Apparatus for Application of Metallic Alloy Coatings,” of which is assigned to the present assignee and is hereby incorporated by reference herein in its entirety.

### GOVERNMENT SUPPORT

This invention was made with government support under the Air Force Grant No. GI 11083. The government has certain rights in the invention.

### BACKGROUND OF THE INVENTION

The present invention provides a method and an apparatus for efficiently applying coating systems and related using a vapor or cluster deposition such as directed vapor deposition (DVD) approach, and more particularly providing a more strain tolerant thermal barrier coating that has improved porosity between columnar grains. The more strain tolerant coating can survive the very large thermal gradient that is encountered in high temperature, very high heat flux environments such as, but not limited thereto, the combustor liner, combustor throat, or exhaust nozzle of a rocket engine.

In rocket engines the combustor side of the liners is exposed to extreme temperatures while the interior is cooled by fuel at a much lower temperature. Use of thermal barrier coatings to protect the cooled liner metal (usually copper) from the hot combustion gasses can produce benefits in performance as well as increased reusability. Thermal barrier coating systems are widely used to provide thermal and oxidation protection of hot section components such as turbine blades and vanes. The high temperature gradient extends into the metallic structure upon which the insulating layer is applied. Thais layer must have very high strength to resist the large compressive stresses. Strengthening mechanisms based upon particulates (dispersoids) can be used for this high temperature strengthening. For best performance, it needs to be applied to the metallic bond coat layer placed over the (copper) substrate. While typical operating temperatures of the hot section of an aircraft turbine is only about 1100-1200° C., the surface of any low conductivity thermal barrier coating of rocket engines will heat to close to the combustion gas temperature, about 2700-3300° C. The cold side of the TBC will be near, or below room temperature due to contact with the cooled copper. This huge thermal gradient will cause the hot side of the system to suffer a thermal compression due to a thermal expansion which varies across the thickness. This will amount to about a three percent linear compression, about nine percent volume (assuming free expansion in the direction of the heat flux due to the free surface). The stresses induced in solids would cause damage to most materials. However, an insulating layer structure containing porosity of a preferred morphology may be able to survive. Any microstructural features to accommodate the strains (such as porosity) must be stable in this high temperature environment.

These and other objects, along with advantages and features of the invention enclosed herein, will be made more apparent from the description, drawings, and claims that follow.

### SUMMARY OF THE INVENTION

The present invention provides a method and an apparatus for efficiently applying coating systems to a surface that can survive the thermal gradient that is encountered in high temperature, high heat flux environments such as a rocket engine or like using vapor or cluster deposition process such as a directed vapor deposition (DVD) approach. To overcome the limitations incurred by conventional methods, exemplary embodiments use an electron or other energetic beam directed vapor deposition (DVD) technique to evaporate and deposit compositionally and morphologically controlled bond coats at high rate while providing a highly strain tolerant thermal barrier coating that has an improved porosity morphology between columnar grains.

Moreover, it should be appreciated that a variety of deposition techniques, methods, and apparatus can be used to evaporate and deposit morphology controlled coating systems of the present invention. Such deposition techniques include, but not limited thereto, the following chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, cluster deposition, and the like.

In one modality, the present invention DVD technique uses the combination of an energetic beam source (e.g., electron or high intensity laser, beam gun) (capable of evaporating material in a low vacuum environment) and a combined inert gas/reactive gas carrier jet of controlled composition to create engineering films. In this system, the vaporized material can be entrained in the carrier gas jet and deposited onto the substrate at a high rate and with high materials utilization efficiency. The velocity and flux of the gas atoms entering the chamber, the nozzle parameters, and the operating chamber pressure can all be significantly varied, facilitating wide processing condition variation and allowing for improved control over the properties of the deposited layer. In particular, under some (higher pressure/high evaporation rate) processing conditions, nanoscopic particles can be reactively formed in the vapor and incorporated in the coating.

In another aspect of the present invention, by employing plasma enhancement, multisource crucibles and appropriate process condition control, the morphology, composition, dispersoid size and concentration, the bondcoat grain size and porosity of deposited layers are all controlled. In a second modality, the present invention uses a different evaporation source to reactively create dispersoids which are then entrained in the vapor plume used for depositing the coating.

In a third modality, dispersoids are created before deposition and are entrained in the noble gas stream and used to transport the bond coat vapor to the component surface. In modalities one, two, and three a plasma may also be used to control the bond coat structure. In all modalities, the result is a low cost deposition approach for applying bond coats which can have compositions and dispersoids distributions which are difficult to deposit using other conventional approaches.

Alternatively, the dispersoid distributions may be optional and therefore omitted in part or entirely from the process.

The DVD apparatus and method comprises a vacuum chamber, energetic beam source (e.g., beam gun), evaporation crucible(s), and inert/reactive gas jet. In addition, a plasma can be created. A substrate bias system capable of applying a DC or alternating potential to at least one of the substrates can then be used for plasma assisted deposition. The electron beam impinges on at least one of the vapor flux sources contained in the crucible. The resulting vapor is entrained in at least one of the carrier gas streams. Hollow cathode arc plasma activation source may or may not be used to ionize at least one of the generated vapor flux and at least one of the carrier gas stream. The ionized or non-ionized generated vapor flux and carrier gas stream are attracted to the substrate surface by allowing a self-bias of the ionized gas and vapor stream or the potential to pull the ionized stream to the substrate.

In an alternative embodiment an end-hall ion source is modified to function as the evaporation and plasma creating system.

It should be appreciated that additional coating layers can be inserted or added between or adjacent to layers shown and illustrated herein.

An embodiment provides a method for forming a thermal barrier coating system. The method comprising: presenting at least one substrate; depositing a bond coat on at least a portion of at least one the substrate; and depositing at least one of zirconia, carbide, boride, refractory metal, zirconia alloy, carbide alloy, boride alloy, and/or refractory metal alloy or any combination thereof to form a deposition of a thermal-insulating layer on the bond coat.

An embodiment provides a method for forming a thermal barrier coating system. The method comprising: presenting at least one substrate; depositing a bond coat on at least a portion of at least one the substrate; depositing at least one of zirconia, carbide, boride, refractory metal, zirconia alloy, carbide alloy, boride alloy, and/or refractory metal alloy or any combination thereof to form a deposition of a thermal-insulating layer on the bond coat comprised of columnar grains; and forming at least one recess in the substrate or the bond coat or at least one recess in each of the substrate and the bond coat, wherein the recess provide gaps between the columnar grains.

An embodiment provides a method for forming a thermal barrier coating system. The method comprising: presenting at least one substrate; placing a screen in a predetermined distance above the substrate; depositing a bond coat on at least a portion of at least one the substrate; depositing at least one of zirconia, carbide, boride, refractory metal, zirconia alloy, carbide alloy, boride alloy, and/or refractory metal alloy, or any combination thereof to form a deposition of a thermal-insulating layer on the bond coat, whereby the screen causes a shadow effect on the deposition.

An embodiment provides a method for forming a thermal barrier coating system. The method comprising: presenting at least one substrate; depositing a bond coat on at least a portion of at least one the substrate; depositing at least a first evaporant source. The first evaporant source comprising: zirconia, carbide, boride, refractory metal, zirconia alloy, carbide alloy, boride alloy, and/or refractory alloy or any combination thereof. Depositing at least a second evaporant source. The second evaporant source comprising: at least one material insoluble with the first evaporant source. The first and second evaporations forming a deposition of a thermal-insulating layer comprised of having columnar grains, wherein the first evaporations produce secondary grains to provide gaps between the columnar grains.

An embodiment provides a method for forming a thermal barrier coating system. The method comprising: presenting at least one substrate; depositing a bond coat on at least a portion of at least one the; providing a sacrificial template in a predetermined distance above the substrate or the bond coat; depositing at least one of zirconia, carbide, boride, refractory metal, zirconia alloy, carbide alloy, boride alloy, and/or refractory metal alloy or any combination thereof to form a deposition of a thermal-insulating layer on the sacrificial template; evaporating the sacrificial template leaving a hollow shell or the like.

An embodiment provides a deposition apparatus for forming a thermal barrier coating system. The apparatus comprising: a housing or any suitable structure, wherein at least one substrate is presented in the housing or at or near suitable structure; a deposition means for depositing a bond coat on at least a portion of at least one the substrate; and the deposition means for depositing at least one of zirconia, carbide, boride, refractory metal, zirconia alloy, carbide alloy, boride alloy, and/or refractory metal alloy or any combination thereof to form a deposition of a thermal-insulating layer on the bond coat.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam: impinging at least one the evaporant source with at least one the energetic beam in the chamber to generate a bond coat evaporated vapor flux, and deflecting at least one of the generated bond coat evaporated vapor flux by at least one of the carrier gas stream, wherein the bond coat evaporated vapor flux at least partially coats at least one of the substrates to form the bond coat. The energetic beam: impinging at least one of the evaporant source with at least one the energetic beam in the chamber to generate a thermal-insulating layer evaporated vapor flux, wherein the evaporant source for generating the thermal-insulating layer comprise at least one of zirconia, carbides, borides, and/or at least one refractory metal or combination thereof or any of their alloys, and deflecting at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat.

An embodiment provides a deposition apparatus for forming a thermal barrier coating system. The apparatus comprising: a housing or suitable structure, wherein at least one substrate is presented in the housing or at or near the suitable housing; a deposition means, the deposition means for depositing a bond coat on at least a portion of at least one the substrate; the deposition means for depositing at least one of zirconia, carbide, boride, refractory metal, zirconia alloy, carbide alloy, boride alloy, and/or refractory metal alloy or any combination thereof to form a deposition of a thermal-insulating layer on the bond coat comprised of columnar grains; and a recess provider means. Also, the recess provider means for forming at least one recess in the substrate or the bond coat or at least one recess in each of the substrate and the bond coat, wherein the recess provide gaps between the columnar grains.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam: impinging at least one the evaporant source with at least one the energetic beam in the chamber to generate a bond coat evaporated vapor flux, and deflecting at least one of the generated bond coat evaporated vapor flux by at least one of the carrier gas stream, wherein the bond coat evaporated vapor flux at least partially coats at least one of the substrates to form the bond coat. The energetic beam: impinging at least one of the evaporant source with at least one the energetic beam in the chamber to generate a thermal-insulating layer evaporated vapor flux, wherein the evaporant source for generating the thermal-insulating layer comprise at least one of zirconia, carbides, borides, and/or at least one refractory metal or combination thereof or any of their alloys, and deflecting at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat comprising columnar grains. Also provided, a recess provider means, the recess provider means for providing at least one recess in at least one of the bond coat or the thermal-insulating layer.

An embodiment provides a deposition apparatus for forming a thermal barrier coating system. The apparatus comprising: a housing, wherein at least one substrate is presented in the housing; a depositing means, the depositing means for depositing a bond coat on at least a portion of at least one the substrate; the depositing means for depositing at least one of zirconia, carbide, boride, refractory metal, zirconia alloy, carbide alloy, boride alloy, and/or refractory alloy, or any combination thereof to form a deposition of a thermal-insulating layer; and a screening means, the securing means causing a shadow effect on the deposition of the thermal-insulating layer.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam: impinging at least one the evaporant source with at least one the energetic beam in the chamber to generate a bond coat evaporated vapor flux, and deflecting at least one of the generated bond coat evaporated vapor flux by at least one of the carrier gas stream, wherein the bond coat evaporated vapor flux at least partially coats at least one of the substrates to form the bond coat. The energetic beam: impinging at least one of the evaporant source with at least one the energetic beam in the chamber to generate a thermal-insulating layer evaporated vapor flux, wherein the evaporant source for generating the thermal-insulating layer comprise at least one of zirconia, carbides, borides and/or at least one refractory metal or combination thereof or any of their alloys, and deflecting at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat comprising columnar grains. Also provided, a screen provider means, the screen provider means for providing a screen while at least one of the bond coat or the thermal insulating layer is being formed.

An embodiment provides a deposition apparatus for forming a thermal barrier coating system. The apparatus comprising: a housing or suitable structure, wherein at least one substrate is presented in the housing or at or near the suitable structure; a depositing means, the depositing means for depositing a bond coat on at least a portion of at least one the substrate. The depositing means for depositing at least a first evaporant source, the first evaporant source comprising: zirconia, carbide, boride, refractory metal, zirconia alloy, carbide alloy, boride alloy, and/or refractory alloy or any combination thereof; the depositing means for depositing at least a second evaporant source. The second evaporant source comprising: at least one material insoluble with the first evaporant source. The first and second evaporations forming a deposition of a thermal-insulating layer comprised of having columnar grains, wherein the first evaporations produce secondary grains to provide gaps between the columnar grains.

An embodiment provides a directed vapor deposition (DVD) apparatus for forming a thermal barrier coating system. The apparatus comprising: a chamber, wherein the chamber has an operating pressure ranging from about 0.1 to about 32,350 Pa, wherein at least one substrate is presented in the chamber; at least one evaporant source disposed in the chamber; at least one carrier gas stream provided in the chamber; and an energetic beam system providing at least one energetic beam. The energetic beam: impinging at least one the evaporant source with at least one the energetic beam in the chamber to generate a bond coat evaporated vapor flux, and deflecting at least one of the generated bond coat evaporated vapor flux by at least one of the carrier gas stream, wherein the bond coat evaporated vapor flux at least partially coats at least one of the substrates to form the bond coat. The energetic beam: impinging at least one of the evaporant source with at least one the energetic beam in the chamber to generate a thermal-insulating layer evaporated vapor flux, wherein the evaporant source for generating the thermal-insulating layer comprise at least one of zirconia, carbides, borides, and/or at least one refractory metal or combination thereof or any of their alloys, and deflecting at least one of the thermal-insulating layer generated evaporated vapor flux by at least one of the carrier gas stream, wherein the thermal-insulating layer evaporated vapor flux at least partially coats at least one of the substrates to form the thermal-insulating layer on the bond coat comprising columnar grains. The energetic beam: impinging at least one of insoluble source with at least one the energetic beam in the chamber to generate secondary grains in the thermal-insulating layer to provide gaps or structured porosity in the columnar grains.

An embodiment provides a coating system on a substrate. The coating system comprising: a bond coat in communication with at least a portion of the substrate, the bond coat produced by deposition technique; and a thermal-insulating layer in communication with at least a portion of the bond coat, the thermal-insulating layer comprising at least one of zirconia, carbide, boride, refractory metal, zirconia alloy, carbide alloy, boride alloy, and/or refractory metal alloy, or any combination thereof.

### BRIEF DESCRIPTION OF THE FIGURES

The foregoing and other objects, features, and advantages of the present invention, as well as the invention itself, will be more fully understood from the following description of preferred embodiments, when read together with the accompanying drawings, in which:

FIGS. 1 and 2 are schematic illustrations of a cross-section partial view of the substrate showing a thermal barrier coating system on the substrate in accordance with exemplary embodiments of this invention.

FIG. 3 is a schematic illustration of a cross-section partial view of the substrate showing a thermal barrier coating system on the substrate in accordance with another embodiment of this invention, wherein indentations/recesses are provide on the substrate and/or bondcoat.

FIG. 4(A) is a schematic illustration of a cross-section partial view showing the shadowing effect of the wire mesh/screen on the inner thermal barrier coating system.

FIG. 4(B) is a representation of the screen/mesh of FIG. 4(A).

FIG. 5 is a schematic illustration of the directed vapor deposition (DVD) processing system. Included in the process are the ability to evaporate from one or more individual source materials and, optionally, the ability to ionize the evaporated flux using hollow cathode plasma activation.

FIG. 6 is a schematic illustration of the hollow cathode plasma activation unit, optionally, used in the present invention DVD apparatus. The cathode plasma activation device emits low energy electrons that ionize the vapor atoms and carrier gas. By properly biasing the substrate the impact energy of both species can be controlled.

FIG. 7 is a schematic illustration of a cross-section partial view of the substrate showing a thermal barrier coating system on the substrate in accordance with another embodiment of this invention, wherein a second material is co-deposited concurrently or intermittently with the refractory coating material.

FIG. 8(A) is a schematic illustration of a partial perspective view of the substrate showing a thermal barrier coating system on the substrate in accordance with another embodiment of this invention, wherein hollow ligaments provide a ceramic layer/thermal insulating layer. Ligaments may be solid if desired or required.

FIG. 8(B) is a schematic enlarged portion of the hollow ligaments shown in FIG. 8(A).

FIG. 8(C) is a schematic enlarged portion of a cross-section of a hollow ligament as shown in FIG. 8(B).

FIG. 9(A) is a photographic depiction of the foam sacrificial template.

FIG. 9(B) is a micrographic depictions of a magnified partial view of the solid ligament foam of the sacrificial template shown in FIG. 9(A).

FIG. 9(C) is a micrographic depictions of a magnified partial view of the solid ligaments of the sacrificial template shown in FIG. 9(B).

### DETAILED DESCRIPTION OF THE INVENTION

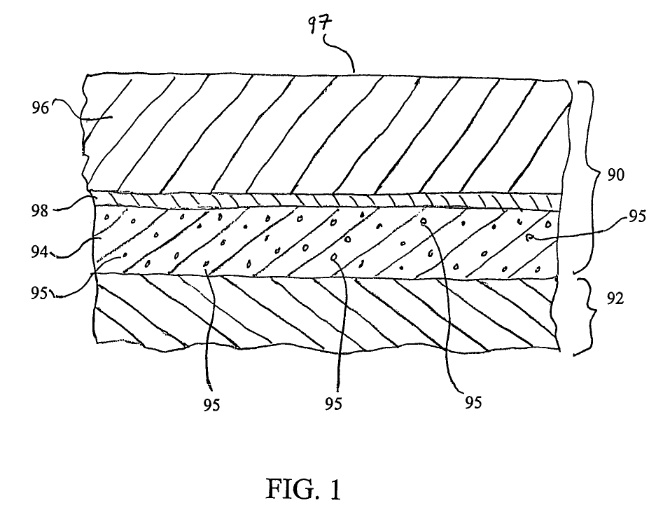

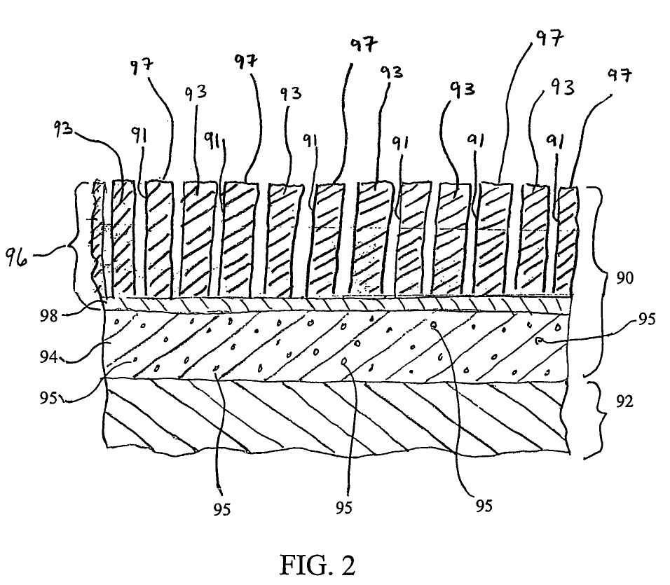

The present invention provides a columnar, thermal protection coating of refractory material with high levels of porosity (equal to or greater than about 10%) between the columns, and the related method and apparatus of making thereof. The porosity between columns (i.e., columnar grains) is necessary, for example but not limited thereto, to allow the coating to survive the thermal gradient that is encountered in high temperature, high heat flux environments such as the combustor liner, combustor throat, or exhaust nozzle of a rocket engine. The porosity allows the effective modulus of the coating to be nearly zero at up to compressive strains of over about three percent (linear). With this level of porosity, no compressive stresses will be generated within the coating during thermal cycling. This coating is schematically shown in FIGS. 1-2, and shall be discussed in greater detail throughout this document.

In gas turbine engines, thermal protection coatings called thermal barrier coatings (TBCs) are used. Here the preferred coating is a columnar ceramic coating with small levels of porosity between the columns (See for example, U.S. Pat. No. 4,321,311 to Strangman, of which is hereby incorporated by reference herein in its entirety). However, the thermal gradient in aircraft engines is small (several hundred degrees F.) compared to the gradients that may be encountered in the rocket engine (several thousand degrees F.). The level of porosity in current TBCs is expected to be insufficient to survive these high thermal gradients of a rocket engine and the resulting high compressive stresses. In a gas turbine engine, the environment is such that the thermal barrier coating system could be exposed to about 1,500° C. However, for a rocket engine, the environment is such that the thermal barrier coating system could be exposed and operated at 3,000° C. and greater.

To survive the high temperatures of a rocket engine or the like, different materials are utilized in the present invention. An oxide of Zirconium (Zr), Zirconia, stabilized by about 7% yttria (an oxide of Yttrium (Y)) can be used in gas turbine TBC applications where a high oxygen activity exists. Zirconia melts at about 2700° C. (4,900° F.). The present invention recognizes that similar and other higher melting temperature materials can be utilized, such as refractory metals Molydenum (Mo), Niobium (Nb), Tantalum (Ta), Titanium (Ti), or Tungsten (W), refractory metal alloys (e.g., but not limited thereto, Titanium alloys (such as TiAl)), or carbides (such as TiC, HfC, ZrC, TaC, W2C, SiC), or borides, or any alloys of the aforementioned refractory metals, carbides or borides. These additional materials include all refractory materials not just oxides since the chemical environment near the coating may or may not be rich in oxygen. Also, other oxides and nitrides may be suitable, for example, but not limited thereto, BN, MgO and BeO due to their very high temperature capability.

As will in greater detail; the present invention uses a microstructure that has a columnar morphology with gaps or porosity between the columns (columnar grains). The gaps at the outer surface should amount to about ten percent or greater of the distance spanning across the opposite-outside limits of two adjacent columns to prevent touching of the columns during the high temperature conditions (i.e., the distance spanning the first column, gap and second column). It should be appreciated that other desired or required size (or shape) gaps can be created as well. At high temperatures sintering of any fine porous features can be expected. Within the columns, fine porosity may exist and this may be lost. This will not be an issue other than to slightly increase the thermal conductivity. However, if the separate columns come into contact due to thermal expansion, then the columns will sinter together and may result in cracking on the subsequent cooling cycle. The methods of the present invention create sufficient porosity and prevent or inhibit sintering, among other things.

The present invention is an improved thermal barrier coating (and related method and system for making the same) which comprises, among other things, a) a substrate typically a nickel base superalloy or copper alloy, b) a bond coat (with or without dispersions for strengthening) and c) a ceramic insulating layer (i.e., thermal insulating layer) or layers on top. A dispersion strengthened bond coat would improve coating system life due to greater yield and creep strength, as well as improving the adhesion of the thermally grown oxide (TGO) layer to the bondcoat and enable top coats of preferred morphology to be nucleated.

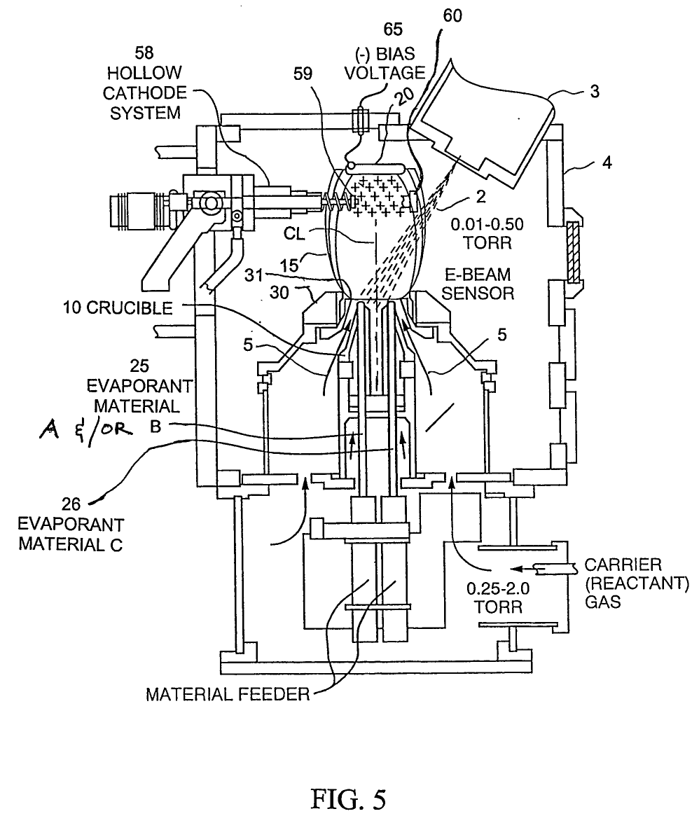

FIG. 5 shows a schematic illustration of the directed vapor deposition process. Using this process, dense nickel aluminide bond coats that are desired for TBC applications have been produced. In DVD, the carrier gas stream 5 is created by a rarefied, inert gas supersonic expansion through a nozzle 30. The speed and flux of the atoms entering the chamber 4, the nozzle parameters, and the operating chamber pressure can all be varied leading to a wide range of accessible processing conditions. As part of the process the supersonic carrier gas stream is maintained by achieving a high upstream pressure (i.e. the gas pressure prior to its entrance into the processing chamber), Pᵤ, and a lower chamber pressure, Pₒ. The ratio of the upstream to downstream pressure along with the size and shape of the nozzle opening 31 controls the speed of the gas entering the chamber 4. The carrier gas molecular weight (compared to that of the vapor) and the carrier gas speed controls its effectiveness in redirecting the vapor atoms via binary collisions towards the substrate 20. As will be discussed later, alternative embodiments of the present invention process will provide other capabilities to evaporate from two or more individual source rods and the ability to ionize the evaporated flux using hollow cathode plasma activation.

Still referring to FIG. 5, the aforementioned DVD process is schematically shown in FIG. 5, improving the deposition efficiency, increasing the deposition rate, providing coating dispersoids, and enhancing the coating uniformity. As will be discussed later, the hollow cathode system 58 is optional based on desired operations. In an embodiment, the carrier gas 5 is realigned so that it is substantially in-line with the crucible 10. In this alignment, the carrier gas flow is placed completely or substantially around the crucible 10 so that the vapor flux 15 no longer has to be turned 90 degrees towards the substrate 20, but rather can be simply focused onto the substrate located directly above the evaporant source 25 for material A and/or B and evaporant source 26 for material C. For example, material A, B and/or C may include Y, Al, Ni, Pt, Co, Mo, Fe, Zr, Hf, Yb, and/or other reactive elements that form the matrix of the bond coat and, optionally, the ceramic dispersoids throughout the bond coat. Moreover, material A, B and/or C may include higher melting temperature materials, such as refractory metals Molydenum (Mo), Niobium (Nb), Tantalum (Ta), Titanium (Ti), or Tungsten (W), refractory metal alloys (e.g., but not limited thereto, Titanium alloys (such as TiAl)), or carbides (such as TiC, HfC, ZrC, TaC, W2C, SiC), or borides, or any alloys of the aforementioned refractory metals, carbides or borides (and/or other elements as desired and required) that form the matrix of the thermal insulation layer/ceramic layer. Additionally, for materials A, B, and/or C other oxides and nitrides may be suitable, for example, but not limited thereto, BN, MgO and BeO due to their very high temperature capability.

The carrier gas 5 flows substantially parallel with the normal axis, identified as CL. Additionally, as will be discussed later herein, the nozzle 30 has a nozzle gap or opening 32, through which carrier gas 5 flows, is designed such that a more optimal carrier gas speed distribution for focusing the vapor 15 is produced. Also shown is the energetic beam source 3, such as electron beam source, laser source, heat source, ion bombardment source, highly focused incoherent light source, microwave, radio frequency, EMF, or combination thereof, or any energetic beams that break chemical bonds.

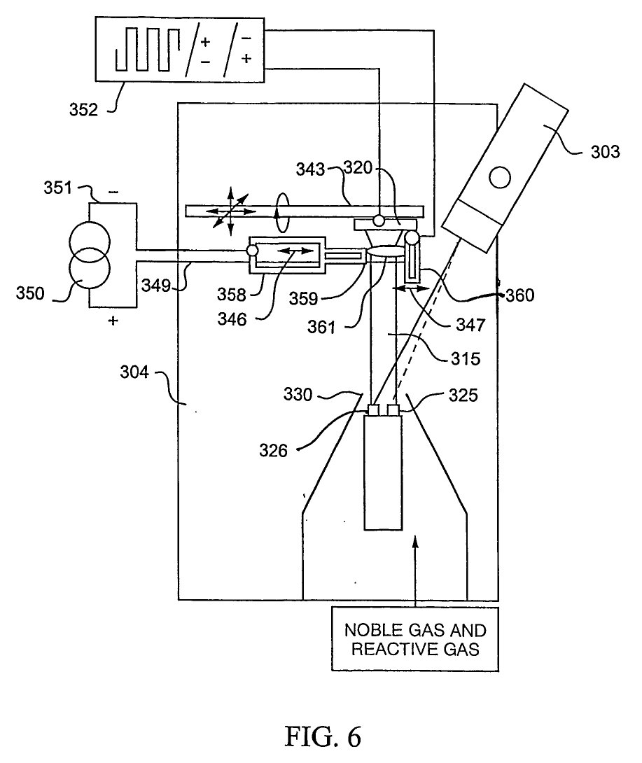

Turning to FIG. 6, the major components of the present invention DVD system including a hollow cathode arc plasma activation and substrate bias supply as schematically shown. The present invention DVD system is comprises a vacuum chamber 304, a first rod feed evaporator 325 (evaporant A & B) and second rod evaporator 326 (evaporant C) that are placed and heated up to evaporation temperature of evaporant by the electron-beam of an electron gun 303 and provides the vapor for coating of substrates 320. Vaporized evaporant is entrained in the supersonic gas and vapor stream 315 formed by the nozzle 330. The substrate(s) 320 are fixed at a substrate holder 343 which enables shift of the substrate in any independent direction and to be swiveled. For example, the translation motion in the horizontal plan allows the exposed surface areas of the substrate to the vapor stream for defined dwelling times and control of the local coating thickness. The vertical motion can be used to keep constant the distance between plasma and surface for curved substrates. Swivel motion, in coordination with the translation motions, can be used to enable the coating of complete three-dimensional parts or can be used also to change the incidence angle of the vapor particles in the course of layer coating in a defined way for getting distinct layer properties. The hollow cathode (arc source) 358 is placed laterally below substrate holder 343 with a short distance between the cathode orifice 359 and the gas and vapor stream 315. The anode 360 is arranged opposite the cathode orifice 359 (i.e., on an approximate distant side of the stream 315) so that the fast electrons and the plasma discharge 361 crosses the gas and vapor stream 315. The fixtures for the cathode 346 and for the anode 347 provide the ability to adjust the distance of the cathode 358 and the anode 360, thereby influencing the diameter and the shape of gas and vapor stream 315.

The plasma discharge 361 is in close proximity (arranged with short distance) to the surface of the substrate 320 enabling close contact between dense plasma and the substrate surface to be coated. In the vicinity of the evaporation electron-beam from the electron gun 303, the anode power line 349 from the power generator 350 to the anode 360 is arranged closely and in parallel with both the plasma discharge 359 and the cathode power line 351, which runs from the cathode to the power generator 350. Between the substrate 320 and the anode 360, a bias generator 352 is applied that allows for generation of a positive, a negative or a periodically alternating voltage between the substrate 320 and the plasma 361.

In all such cases, the ability to deposit compositionally controlled coatings efficiently, uniformly, at a high rate, with high part throughput, and in a cost-effective manner is desired. Some illustrative examples of deposition systems are provided in the following applications and patents and are co-assigned to the present assignee 1) U.S. Pat. No. 5,534,314, filed Aug. 31, 1994, entitled “Directed Vapor Deposition of Electron Beam Evaporant,” 2) U.S. Pat. No. 5,736,073, filed Jul. 8, 1996, entitled “Production of Nanometer Particles by Directed Vapor Deposition of Electron Beam Evaporant,” 3) U.S. Pat. No. 6,478,931 B1, filed Aug. 7, 2000, entitled “Apparatus and Method for Intra-layer Modulation of the Material Deposition and Assist Beam and the Multilayer Structure Produced There from,” and corresponding Divisional U.S. application Ser. No. 10/246,018, filed Sep. 18, 2002, 4) International Application No. PCT/US01/16693, filed May 23, 2001 entitled “A process and Apparatus for Plasma Activated Deposition in a Vacuum,” and corresponding U.S. application Ser. No. 10/297,347, filed Nov. 11, 2002, and 5) International Application No. PCT/US02/13639, filed Apr. 30, 2002 entitled “Method and Apparatus for Efficient Application of Substrate Coating;” of which all of these patents and applications are hereby incorporated by reference herein in their entirety.

Other U.S. Patents, Applications, and Publications that are hereby incorporated by reference herein in their entirety include the following:
1. U.S. Publication No. 2003/0180571 A1 to Singh
2. U.S. Publication No. 2003/0138660 A1 to Darolia et al.
3. U.S. Publication No. 2003/0129378 A1 to Movchan et al.
4. U.S. Publication No. 2003/0129316 A1 to Darolia et al.
5. U.S. Publication No. 2003/0118874 A1 to Murphy
6. U.S. Publication No. 2002/0110698 A1 Singh
7. U.S. Pat. No. 6,630,199 B1 to Austin et al.
8. U.S. Pat. No. 6,585,878 B2 to Stangman et al.
9. U.S. Pat. No. 6,528,118 B2 to Lee et al.
10. U.S. Pat. No. 6,485,845 B1 to Wustman et al.
11. U.S. Pat. No. 6,461,746 B1 to Darolia et al.
12. U.S. Pat. No. 6,455,167 B1 to Rigney et al.
13. U.S. Pat. No. 6,444,331 B2 to Ritter et al.
14. U.S. Pat. No. 6,440,496 B1 to Gupta et al.
15. U.S. Pat. No. 6,436,473 B2 to Darolia et al.
16. U.S. Pat. No. 6,395,343 B1 to Strangman
17. U.S. Pat. No. 6,306,524 B1 to Spitsberg et al.
18. U.S. Pat. No. 6,291,084 B1 to Darolia et al.
19. U.S. Pat. No. 6,273,678 B1 to Darolia
20. U.S. Pat. No. 6,258,467 B1 to Subramanian
21. U.S. Pat. No. 6,255,001 B1 to Darolia
22. U.S. Pat. No. 6,203,927 B1 to Subramanian et al.
23. U.S. Pat. No. 6,168,874 B1 to Gupta et al.
24. U.S. Pat. No. 6,153,313 to Rigney et al.
25. U.S. Pat. No. 6,123,997 to Schaeffer et al.
26. U.S. Pat. No. 6,096,381 to Zheng
27. U.S. Pat. No. 5,712,050 to Goldman et al
28. U.S. Pat. No. 5,498,484 to Duderstadt
29. U.S. Pat. No. 5,419,971 to Skelly et al.
30. U.S. Pat. No. 4,321,311 to Strangman

Turning to FIG. 1, FIG. 1 schematically represents a TBC system 90 of a type that benefits from the teachings of this invention. As shown, the coating system 90 includes a ceramic layer (thermal insulating layer) 96 bonded to the substrate 92 with an overlay bond coat 94. Optionally, the bond coat 94 may have ceramic dispersoids 95 of oxygen or other compounds dispersed at least substantially throughout as shown. To attain the dispersoids the ceramic is reactively created during or intermittently during the deposition process. The substrate 92 (e.g., combustion liner, etc.) is preferably a high-thermal conductivity, high-temperature material, such as copper, nickel or cobalt-base superalloy. To attain a strain-tolerant columnar grain structure, the ceramic layer 96 is deposited by the desired deposition technique. Exemplary high melting temperature material for the ceramic layer (thermal insulating layer) 96 are, but not limited thereto, refractory metals Molydenum (Mo), Niobium (Nb), Tantalum (Ta), Titanium (Ti), or Tungsten (W), refractory metal alloys (e.g., but not limited thereto, Titanium alloys (such as TiAl)), or carbides (such as TiC, HfC, ZrC, TaC, W2C, SiC), or borides, or any alloys of the aforementioned refractory metals, carbides or borides. Additionally, other oxides and nitrides may be suitable, for example, but not limited thereto, BN, MgO and BeO due to their very high temperature capability. The ceramic layer 96 is deposited to a thickness that is sufficient to provide the required thermal protection for the underlying substrate 92, generally on the order of about 50 to about 300 micrometers, or as desired or required. The surface of the bond coat 94 oxidizes to form an aluminum oxide surface layer (alumina scale) 98 to which the ceramic layer 96 chemically bonds.

The present invention directed vapor deposition (DVD) apparatus and related method provide the technical basis for a small volume, low cost coating process capable of depositing the bond coat of a thermal barrier coating (TBC) system. DVD technology utilizes a trans-sonic gas stream to direct and transport a thermally evaporated vapor cloud to a component.

In an alternative embodiment, to endow the DVD process with the ability to create dense, crystalline coatings, a plasma activation unit is incorporated into the DVD system.

Turning to FIG. 2, FIG. 2 schematically represents a TBC system 90 of a type that benefits from the teachings of this invention. The columnar grains 93 are oriented substantially perpendicular to the surface of the substrate 92. Between at least some of the columnar grains 93 are microns sized gaps 91 extending from the outer surface 97 (or, while not illustrated, only part of the length of the columnar grains 93) of the ceramic layer 96.

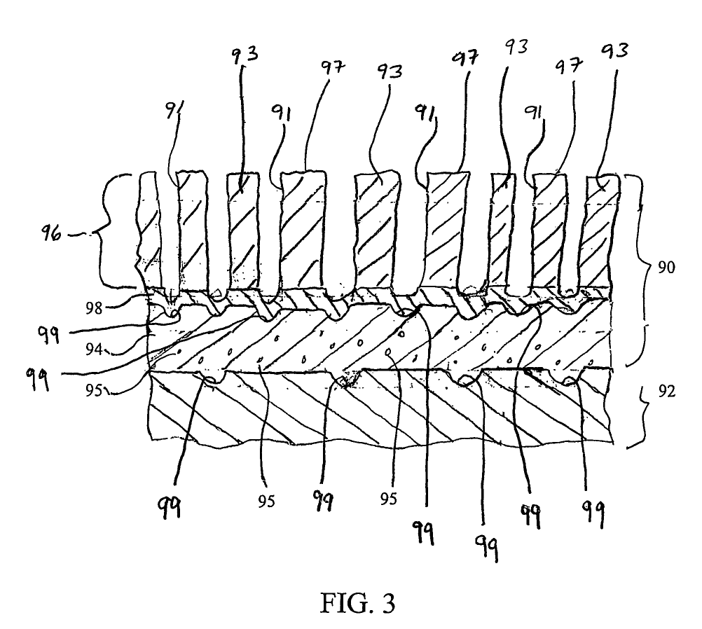

Turning to FIG. 3, indentations/recesses 99 on the substrate 92 are provided to prevent crack propagation at the interface between the bond coat 94 and substrate 92. Alternatively, the indentations/recesses 99 may be made on the he bond coat 94 or both the substrate 92 and the bond coat 94 or any other layer as desired. The indentations 99 promote gaps 91 between the growth columnar grains 93. The indentation/recess 99 may be any plurality and type having a variety of shapes, patterns, and sizes, so as to provide a columnar gap inducing geometry. Such shapes and patterns may include, for example, aperture, port, duct, groove, channel, dimple, bore, inlet, outlet, hole, conduit, perforation, channel, passage, pipe, tube, slot, flute, well, tunnel, etc. The indentations may be any preselected pattern of three-dimensional features wherein the preselected pattern has a crack-impeding geometry. The ablation, etching, removal, etc. of the layers may be made by a variety of techniques including laser removal, photoengraving, lithographic, mask applications, micromachining, or as desired or required as appreciated by one skilled in the art.

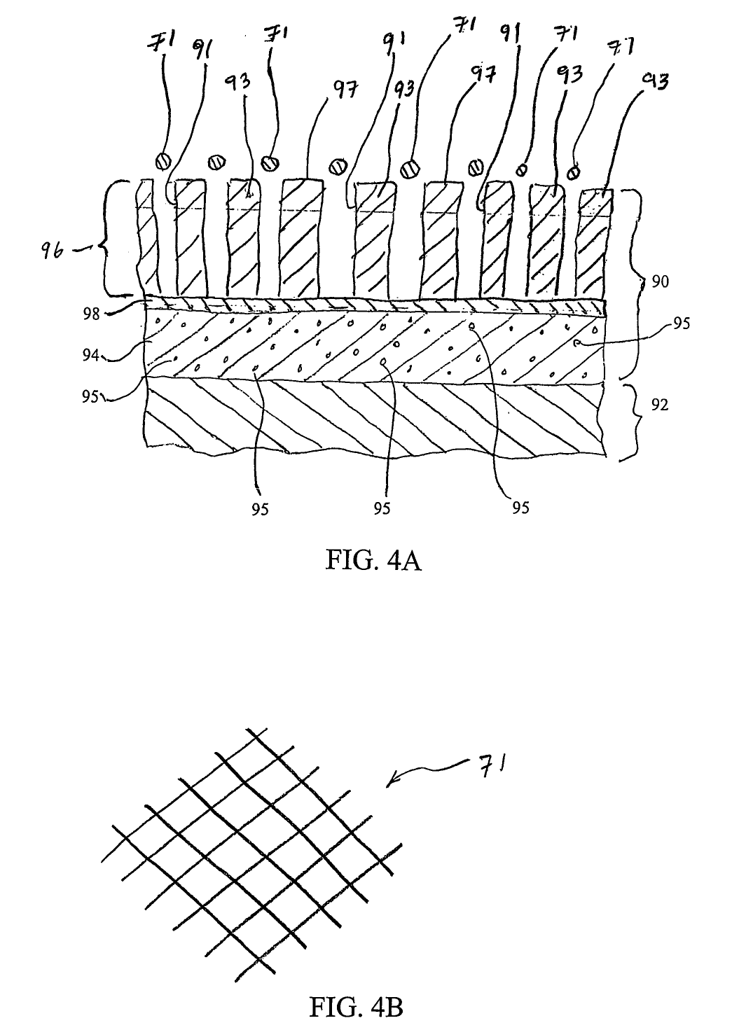

Turning to FIG. 4(A), a screen 71, mesh or other desired object (e.g., mask) is placed over the substrate 92 while depositing the thermal insulating layer 96 through the screen 71 to produce shadows thereby forming the columns 93 and respective gaps 91. A representation of the screen 71 is shown in FIG. 4(B). The screen 71 determines the configuration of the structured gaps 91, i.e., structured porosity. For example, the screen or wire mesh design (the mesh size, plurality, pattern and wire diameter) determines the internal dimensions of and the spacing (structured porosity) between the resultant structured gaps 91. Although illustrated as a grid, it should be appreciated other physical forms may be utilized, for example, serpentine rows or random patterns. By manipulating the screen 71 or the like during TBC deposition, the geometric pattern of the resultant structure is determined.

It should be appreciated that the screen 71 may be below, in contact with, or close proximity to the surface 97, or any other desired location. The screen 71 can become incorporated into the thermal barrier coating system 90, for example, the bond coat 94 and ceramic layer 96. The lower melting point of the screen 71 material allows it to melt and create either real or virtual porosity at the elevated temperature.

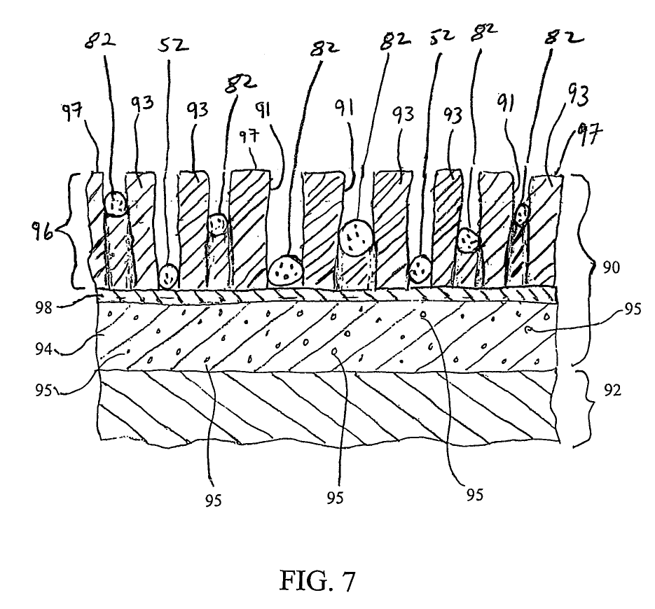

Turning to FIG. 7, in another embodiment, the process is to co-deposit a second material concurrently or intermittently with the refractory coating material to provide secondary grains or structures. If the second material is insoluble with the refractory material, then, under appropriate deposition conditions, the refractory may grow in a columnar structure with the second material between the columns (columnar grains). The second material is subsequently removed to leave gaps. As mentioned throughout, the refractory material may be any appropriate high temperature (refractory) material such as tungsten, intermetallic compounds (such as TiAl), borides, carbides or some high temperature oxides (such as zirconia). Materials (e.g., Mo) whose oxides form a stable vapor are particularly interested for this sacrificial application.

For an embodiment pertaining to the co-evaporation of an insoluble material with the refractory material, the lower melting characteristic of the second material will form dense recrystallized grains or secondary grains between the columnar structures of the refractory material. The insoluble material can be metallic or an inorganic material such as salt. Removal of the insoluble material can be by special operation, such as dissolving a salt in water before use of the rocket thermal protection coating or it can be melted out in initial service of the engine or the like.

Still referring to FIG. 7, the secondary grains 82 promote gaps 91 between the growth columnar grains 93.

Next, in other embodiments, a sacrificial template is applied to the surface, i.e., a predetermined surface such as the substrate 92 or bond coat 94 or as desired or required. The coating(s) is formed around or through this template and the template is subsequently removed (by dissolution, evaporation, combustion, or other reaction). The template could be of any topology that results in a coating of high porosity (low effective thermal conductivity) and large gaps to accommodate expansion on heating. For example, but not limited thereto, the sacrificial template may be reticulated polymer or metal foam which is subsequently removed leaving behind a 3D interconnected network of pores. The pore diameter and volume fraction is then controlled by selection of the reticulated foam.

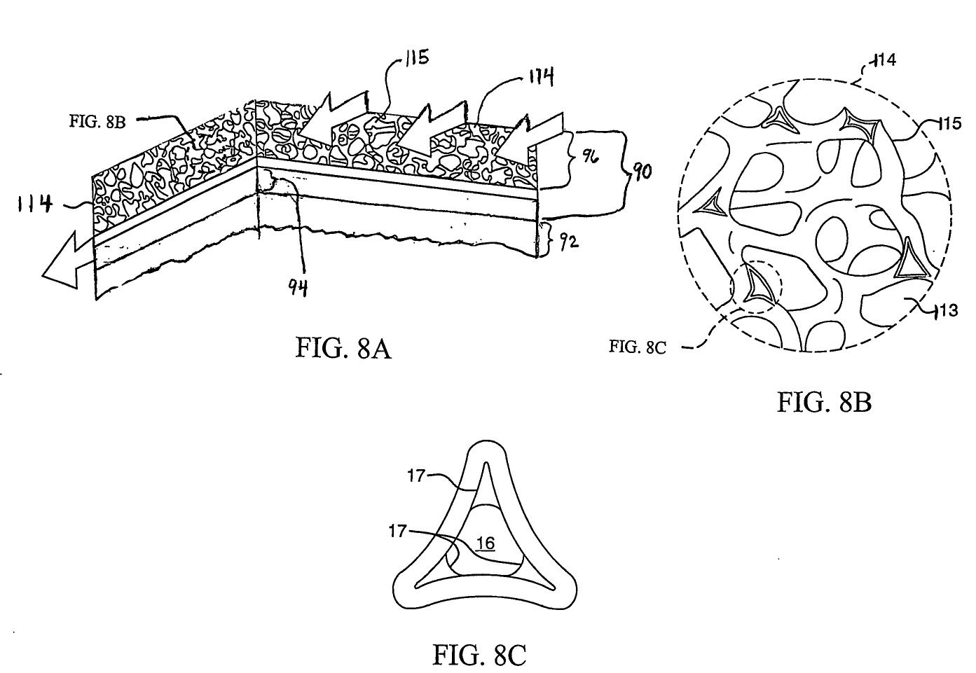

Turning to FIGS. 8(A)-(C), which show a schematic representation of the present invention hollow ligaments 15 providing a ceramic layer 96. Compared to solid ligaments, the hollow ligaments of the present invention provide effective and improved porosity. The three-dimensional aspects of the ligaments 15 also provide benefits when considering the cooling fluid cross flow of as denoted by arrows CF, shown in FIG. 8(A).

Still referring to FIGS. 8(A)-(C), FIG. 8(A) is a schematic perspective view of a preferred embodiment of TBC system 90 of a type that benefits from the teachings of this invention. FIG. 1(B) shows a schematic magnified view of the reticulated foam structure 114 showing the hollow ligaments 115 and interstitial volume 113 surrounding the same. FIG. 8(C) is a further magnification showing the cross sectional shape of a typical hollow ligament 15 and portion of the internal volume 116 enclosed therein with a working fluid 117. Examples of working fluid are, but not limited thereto, air, any desired fluid, gas, etc.

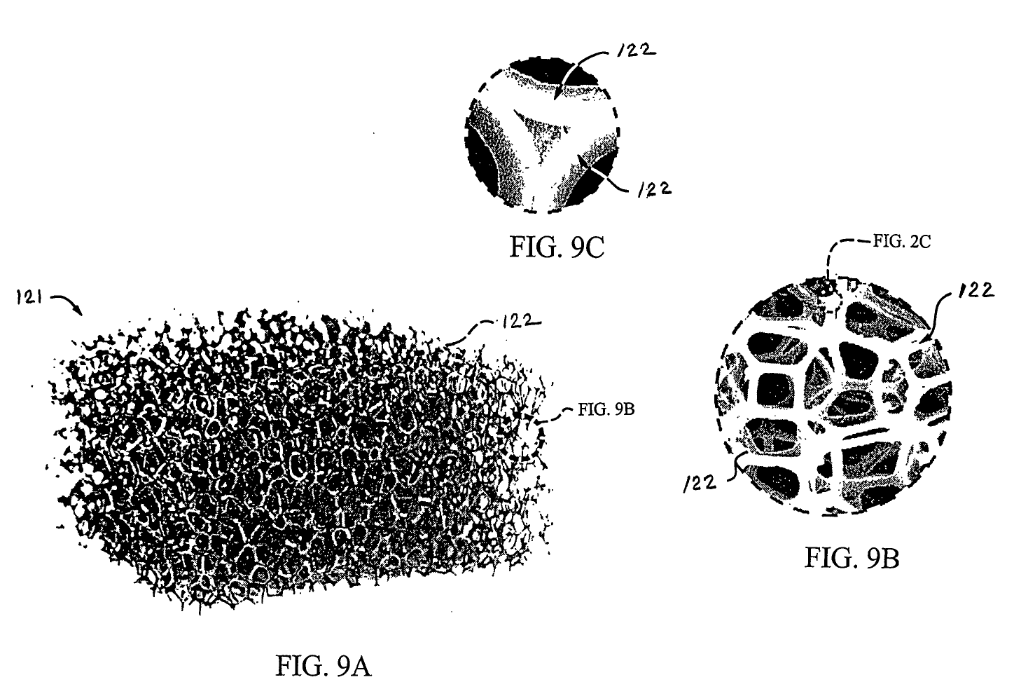

FIGS. 9(A)-(C) show a foam sacrificial template 121 having solid ligaments 122 comprised of a predetermined material, for example polyurethane, polyester, polyethylene, polyamide, polyvinyl chloride, polypropylene, and polystyrene, or any sacrificial template such as water soluble salt, oxidizable graphite, an easily decomposed polymer, meltable wax or the like. FIG. 9(A) is a photographic depiction of the foam sacrificial template 121, and FIGS. 9(B)-(C), are micrographic depictions of a magnified partial view of the solid ligaments 122 shown in FIG. 9(A). The process of creating a hollow ligament foam utilizing a solid ligament foam 121 is as follows. A preferred method of producing a desirable hollow ligament open cell foam or periodic network structure is to coat a solid ligament open cell foam or network structure (i.e., template) with a coating material, and then evaporate away the solid ligament foam material, leaving a hollow ligament shell, i.e., reticulated foam structure 114 as shown in FIGS. 8(A)-(C). Also, further aspects of creating and utilizing hollow ligament core can be found in co-pending and co-assigned PCT International Application No. PCT/US01/22266, filed on Jul. 16, 2001, entitled “Heat Exchange Foam,” and corresponding U.S. application Ser. No. 10/333,004, filed Jan. 14, 2003, entitled “Method and Apparatus for Heat Exchange Using Hollow Foams and Interconnected Networks and Method of Making the Same,” of which are hereby incorporated by reference herein in their entirety. A preferred solid ligament foam is polyurethane foam, like that which is available from Crest Foam Industries, Inc. of Moonachie, N.J., which has cell sizes in the range of about 5 ppi to 120 ppi, possesses cusp-shaped ligaments (roughly triangular in cross sectional shape), is easy to evaporate at relatively low temperature, and is inexpensive to acquire.

It should further be appreciated that the sacrificial template may be a variety of structures (with hollow or solid ligaments) including, for example, solid ligament foam structure, hollow ligament foam structure, mesh structure, stacked mesh structure, screen structure, stacked screen structure, interwoven wires structure, serpentine rows, random pattern structure, 3-D array structure, truss structure, tubes structure, periodic cells structure, stochastic cells structure, or any combination thereof.

According to the design criteria discussed throughout, other two-dimensional and three-dimensional structures may be implemented with the present invention as provided in co-pending and co-assigned PCT International Application No. PCT/US01/17363, entitled “Multifunctional Periodic Cellular Solids and the Method of Making thereof,” filed on May 29, 2001, and corresponding U.S. application Ser. No. 10/296,728, filed Nov. 25, 2002, of which are hereby incorporated by reference herein in their entirety.

According to the design criteria discussed throughout, other two-dimensional and three-dimensional structures may be implemented with the present invention as shown in co-pending and co-assigned PCT International Application No. PCT/US02/17942, entitled “Multifunctional Periodic Cellular Solids and the Method of Making thereof,” filed on Jun. 6, 2002, of which is hereby incorporated by reference herein in its entirety.

According to the design criteria discussed throughout, other two-dimensional and three-dimensional structures may be implemented with the present invention as shown in co-pending and co-assigned PCT International Application No. PCT/US03/16844, entitled “Method for Manufacture of Periodic Cellular Structure and Resulting Periodic Cellular Structure,” filed on May 29, 2003, of which is hereby incorporated by reference herein in its entirety.

The present invention provides thermal protection coating method and resultant coating product for use is effective at extremely high temperatures and in high thermal gradients. An application of the present invention is for rocket engine combustion chamber liners, but not limited thereto. Other applications may include, for example, but not limited thereto: rocket engine combustion chamber and exhaust nozzle; rocket engine turbo pump; space re-entry vehicles; leading edge of Scram Jets and other hypersonic vehicles; thermal protection system for fusion reactors; TBC for future (or other applicable) gas turbine engines; solar powered rocked engines; heat exchangers; space and missile propulsion systems. It should appreciated that the present invention coating system can be utilized for applications with lower operating conditions.

The present invention coating has a unique combination of high temperature refractory materials, etc. and engineered microstructures that will allow it to survive under hostile conditions. The heat load on the structural members of the rocket engine, for example, can be greatly reduced with use of this coating, allowing rocket designers to improve engine performance and reduce life cycle costs, among other objectives and advantages.

The present invention provides thermal protection coating method and resultant product for use that can with stand high temperatures while preventing or inhibiting adverse spallation or otherwise degradation.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of the appended claims. For example, regardless of the content of any portion (e.g., title, section, abstract, drawing figure, etc.) of this application, unless clearly specified to the contrary, there is no requirement for any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Accordingly, the descriptions and drawings are to be regarded as illustrative in nature, and not as restrictive.

The invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims rather than by the foregoing description, and all changes which come within the meaning and range of equivalency of the claims are therefore intended to be embraced herein.

1. A method for forming a thermal barrier coating system, the method comprising:
presenting at least one substrate;
depositing a bond coat on at least a portion of at least one said substrate; and
depositing at least one of zirconia, carbide, boride, refractory metal, zirconia alloy, carbide alloy, boride alloy, and/or refractory metal alloy or any combination thereof to form a deposition of a thermal-insulating layer on said bond coat.

2. The method of claim 1, wherein:
said refractory metal comprise at least one of Molydenum (Mo), Niobium (Nb), Tantalum (Ta), Titanium (Ti), or Tungsten (W), or any combination thereof; and
said refractory metal alloy comprise at least one of alloys of Mo, Nb, Ta, Ti or W, or any combination thereof.

3. The method of claim 1, wherein said carbide material comprise at least one of TiC, HfC, ZrC, TaC, W2C, SiC, alloys of TiC, HfC, ZrC, TiAl, TaC, W2C, SiC, or any combination thereof.

4. The method of claim 1, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

5. The method of claim 1, wherein said deposition of said bond coat and thermal insulating layer is accomplished with a Directed Vapor Deposition (DVD).

6. The method of claim 5, wherein said DVD technique comprises:
said presenting of at least one of said substrate includes presenting said substrate to a chamber, wherein said chamber has an operating pressure ranging from about 0.1 to about 32,350 Pa,;
presenting at least one additional evaporant sources to said chamber if desired;
presenting at least one carrier gas stream to said chamber;
impinging said zirconia and/or at least one refractory metal or combination thereof or any of their alloys and/or said desired evaporant source with at least one energetic beam in said chamber to generate an evaporated vapor flux impinged by said electron beam; and
deflecting at least one of said generated evaporated vapor flux by at least one of said carrier gas stream, wherein said evaporated vapor flux:
at least partially coats at least one said substrate to form said bond coat, and
at least partially coats said bond coat to form said thermal-insulating layer coat.

7. The method of claim 6, wherein said energetic beam comprises at least one of electron beam source, laser source, heat source, ion bombardment source, highly focused incoherent light source, microwave, radio frequency, EMF, or any energetic beam that break chemical bonds, or any combination thereof.

8. The method of claim 6, further comprising:
said chamber further includes a substrate bias system capable of applying a DC or alternating potential to at least one of said substrates;
impinging said at least one of said generated vapor flux and at least one of said carrier gas stream with a working gas generated by at least one hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

9. The method of claim 8, said generated electrons from said hollow cathode source is regulated for direction through variations in the quantity of working gas passing through said hollow cathode source.

10. The process of claim 8, wherein the distance between said cathode source and said generated evaporated vapor flux is regulated for ionization of the entire generated evaporated vapor flux.

11. The method of claim 6, further comprising at least one nozzle, wherein said at least one carrier gas stream is generated from said at least one nozzle and said at least one evaporant source is disposed in said at least one nozzle

12. The method claim 11, wherein said evaporant retainer is a crucible.

13. The method of claim 6, further comprising:
said chamber further includes a substrate bias system capable of applying a DC or alternating potential to at least one of said substrates;
impinging said at least one of said generated vapor flux and at least one of said carrier gas stream with a low energy beam to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

14. The method of claim 6, wherein at least one of said at least one desired additional evaporant source is a material selected from the group consisting: NiY, NiAl, PtAl, PtY, Ni, Y, Al, Pt, NiAlPt, NiYPt, NiPt, Co, Mo, Fe, Zr, Hf, Yb, and other reactive elements.

15. The method of claim 6, wherein at least one of said at least one desired additional evaporant sources is made from alloys formed of one or more of a material selected from the group consisting: NiY, NiAl, PtAl, Pty, Ni, Y, Al, Pt, NiAlPt, NiYPt, NiPt, Co, Mo, Fe, Zr, Hf, Yb, and other reactive elements.

16. A method for forming a thermal barrier coating system, the method comprising:
presenting at least one substrate;
depositing a bond coat on at least a portion of at least one said substrate;
depositing at least one of zirconia, carbide, boride, refractory metal, zirconia alloy, carbide alloy, boride alloy, and/or refractory metal alloy or any combination thereof to form a deposition of a thermal-insulating layer on said bond coat comprised of columnar grains; and
forming at least one recess in said substrate or said bond coat or at least one recess in each of said substrate and said bond coat, wherein said recess provide gaps between the columnar grains.

17. The method of claim 16, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

18. The method of claim 16, wherein said deposition of said bond coat and thermal insulating layer is accomplished with a directed vapor deposition (DVD).

19. A method for forming a thermal barrier coating system, the method comprising:
presenting at least one substrate;
placing a screen in a predetermined distance above said substrate;
depositing a bond coat on at least a portion of at least one said substrate;
depositing at least one of zirconia, carbide, boride, refractory metal, zirconia alloy, carbide alloy, boride alloy, and/or refractory metal alloy, or any combination thereof to form a deposition of a thermal-insulating layer on said bond coat, whereby said screen causes a shadow effect on the deposition.

20. The method of claim 19, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

21. The method of claim 19, wherein said deposition of said bond coat and thermal insulating layer is accomplished with a Directed Vapor Deposition (DVD).

22. A method for forming a thermal barrier coating system, the method comprising:
presenting at least one substrate;
depositing a bond coat on at least a portion of at least one said substrate;
depositing at least a first evaporant source, said first evaporant source comprising:
zirconia, carbide, boride, refractory metal, zirconia alloy, carbide alloy, boride alloy, and/or refractory alloy or any combination thereof;
depositing at least a second evaporant source, said second evaporant source comprising:
at least one material insoluble with said first evaporant source;
said first and second evaporations forming a deposition of a thermal-insulating layer comprised of having columnar grains, wherein said first evaporations produce secondary grains to provide gaps between the columnar grains.

23. The method of claim 22, wherein said insoluble material comprise at least one of metal, alloys, or salt, or any combination thereof.

24. The method of claim 22, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

25. The method of claim 22, wherein said deposition of said bond coat and thermal insulating layer is accomplished with a Directed Vapor Deposition (DVD).

26. A method for forming a thermal barrier coating system, the method comprising:
presenting at least one substrate;
depositing a bond coat on at least a portion of at least one said;
providing a sacrificial template in a predetermined distance above said substrate or said bond coat;
depositing at least one of zirconia, carbide, boride, refractory metal, zirconia alloy, carbide alloy, boride alloy, and/or refractory metal alloy or any combination thereof to form a deposition of a thermal-insulating layer on said sacrificial template;
evaporating said sacrificial template leaving a hollow shell.

27. The method of claim 26, wherein said sacrificial template comprises at least one of solid ligament foam structure, hollow ligament foam structure, mesh structure, stacked mesh structure, screen structure, stacked screen structure, interwoven wires structure, serpentine rows, random pattern structure, 3-D array structure, truss structure, tubes structure, periodic cells structure, stochastic cells structure, 3-D cellular structure, 3-D cellular truss or any combination thereof.

28. The method of claim 26, wherein said deposition of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

29. The method of claim 26, wherein said deposition of said bond coat and thermal insulating layer is accomplished with a Directed Vapor Deposition (DVD).

30. A deposition apparatus for forming a thermal barrier coating system, the apparatus comprising:
a housing, wherein at least one substrate is presented in said housing;
a deposition means for depositing a bond coat on at least a portion of at least one said substrate; and
said deposition means for depositing at least one of zirconia, carbide, boride, refractory metal, zirconia alloy, carbide alloy, boride alloy, and/or refractory metal alloy or any combination thereof to form a deposition of a thermal-insulating layer on said bond coat.

31. The apparatus of claim 30, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

32. The apparatus of claim 30, wherein said deposition means comprises:
a directed vapor deposition (DVD) apparatus.

33. The method of claim 30, wherein:
said refractory metal comprise at least one of Molydenum (Mo), Niobium (Nb), Tantalum (Ta), Titanium (Ti), or Tungsten (W), or any combination thereof; and
said refractory metal alloy comprise at least one of alloys of Mo, Nb, Ta, Ti or W, or any combination thereof.

34. The method of claim 30, wherein said carbide material comprise at least one of TiC, HfC, ZrC, TaC, W2C, SiC, alloys of TiC, HfC, ZrC, TiAl, TaC, W2C, SiC, or any combination thereof.

35. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam, said energetic beam:
impinging at least one said evaporant source with at least one said energetic beam in said chamber to generate a bond coat evaporated vapor flux, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprise at least one of zirconia, carbides, borides, and/or at least one refractory metal or combination thereof or any of their alloys, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat.

36. The method of claim 35, wherein said energetic beam comprises at least one of electron beam source, electron gun source, laser source, heat source, ion bombardment source, highly focused incoherent light source, microwave, radio frequency, EMF, or any energetic beam system that breaks chemical bonds, or combination thereof.

37. The apparatus of claim 35, further comprising:
a substrate bias system capable of applying a DC or alternating potential to at least one of said substrates;
at least one hollow cathode arc source generating a low voltage beam, said at least one hollow cathode arc source:
impinging said at least one of said generated vapor flux and at least one of said carrier gas stream with a working gas generated by at least one said hollow cathode arc plasma activation source to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

38. The apparatus of claim 37, wherein said hollow cathode arc source comprises at least one cathode orifice wherein a predetermined selection of said cathode orifices are arranged in close proximity to the gas and vapor stream; and
an anode is arranged opposite of said cathode source wherein the gas and vapor stream is there between said cathode source and said anode.

39. The apparatus of claim 35, further comprising at least one nozzle, wherein said at least one carrier gas stream is generated from said at least one nozzle and said at least one evaporant source is disposed in said at least one nozzle, wherein said at least one said nozzle comprises:
at least one nozzle gap wherein said at least one said carrier gas flows there from; and
at least one evaporant retainer for retaining at least one said evaporant source, said evaporant retainer being at least substantially surrounded by at least one said nozzle gap.

40. The apparatus of claim 39, wherein said evaporant retainer is a crucible.

41. The apparatus of claim 35, further comprising:
a substrate bias system capable of applying a DC or alternating potential to at least one of said substrates;
at least one low energy beam source for generating a low voltage beam, said at least one low energy beam source:
impinging said at least one of said generated vapor flux and at least one of said carrier gas stream with a low energy beam to ionize said at least one of said generated vapor flux and at least one of said carrier gas stream; and
attracting said ionized generated vapor flux and said carrier gas stream to a substrate surface by allowing a self-bias of said ionized gas and vapor stream or said potential to pull the ionized stream to said substrate.

42. A deposition apparatus for forming a thermal barrier coating system, the apparatus comprising:
a housing, wherein at least one substrate is presented in said housing;
a deposition means, said deposition means for depositing a bond coat on at least a portion of at least one said substrate;
said deposition means for depositing at least one of zirconia, carbide, boride, refractory metal, zirconia alloy, carbide alloy, boride alloy, and/or refractory metal alloy or any combination thereof to form a deposition of a thermal-insulating layer on said bond coat comprised of columnar grains; and
a recess provider means, said recess provider means for forming at least one recess in said substrate or said bond coat or at least one recess in each of said substrate and said bond coat, wherein said recess provide gaps between the columnar grains.

43. The apparatus of claim 42, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

44. The apparatus of claim 42, wherein said deposition means comprises:
a directed vapor deposition (DVD) apparatus.

45. The apparatus of claim 42, wherein said recess provider means comprises at least one of:
etching device, masking device, tooling device, laser device, drilling device, energetic beam device, ablation device, hammering device, photoengraving device, lithographic device, and micromachining device.

46. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam,
said energetic beam:
impinging at least one said evaporant source with at least one said energetic beam in said chamber to generate a bond coat evaporated vapor flux, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprise at least one of zirconia, carbides, borides, and/or at least one refractory metal or combination thereof or any of their alloys, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat comprising columnar grains; and
a recess provider means, said recess provider means for providing at least one recess in at least one of said bond coat or said thermal-insulating layer.

47. The apparatus of claim 46, wherein said recess provider means comprises at least one of:
etching device, masking device, tooling device, laser device, drilling device, energetic beam device, ablation device, hammering device, photoengraving device, lithographic device, and micromachining device.

48. A deposition apparatus for forming a thermal barrier coating system, the apparatus comprising:
a housing, wherein at least one substrate is presented in said housing;
a depositing means, said depositing means for depositing a bond coat on at least a portion of at least one said substrate;
said depositing means for depositing at least one of zirconia, carbide, boride, refractory metal, zirconia alloy, carbide alloy, boride alloy, and/or refractory alloy, or any combination thereof to form a deposition of a thermal-insulating layer; and
a screening means, said securing means causing a shadow effect on the deposition of said thermal-insulating layer.

49. The apparatus of claim 48, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

50. The apparatus of claim 48, wherein said deposition means comprises:
a directed vapor deposition (DVD) apparatus.

51. The apparatus of claim 48, wherein said screening means being located at at least one predetermined distance above said substrate.

52. The apparatus of claim 48, wherein:
said screening means being located at a at least one predetermined distance above said substrate; and
said screening means comprising at least one of screen, mesh, and/or mask, or any combination thereof.

53. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam,
said energetic beam:
impinging at least one said evaporant source with at least one said energetic beam in said chamber to generate a bond coat evaporated vapor flux, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprise at least one of zirconia, carbides, borides and/or at least one refractory metal or combination thereof or any of their alloys, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat comprising columnar grains; and
a screen provider means, said screen provider means for providing a screen while at least one of said bond coat or said thermal insulating layer is being formed.

54. A deposition apparatus for forming a thermal barrier coating system, the apparatus comprising:
a housing, wherein at least one substrate is presented in said housing;
a depositing means, said depositing means for depositing a bond coat on at least a portion of at least one said substrate;
said depositing means for depositing at least a first evaporant source, said first evaporant source comprising:
zirconia, carbide, boride, refractory metal, zirconia alloy, carbide alloy, boride alloy, and/or refractory alloy or any combination thereof;
said depositing means for depositing at least a second evaporant source, said second evaporant source comprising:
at least one material insoluble with said first evaporant source;
said first and second evaporations forming a deposition of a thermal-insulating layer comprised of having columnar grains, wherein said first evaporations produce secondary grains to provide gaps between the columnar grains.

55. The apparatus of claim 54, wherein said deposition means comprises:
at least one of directed vapor deposition (DVD) apparatus, chemical vapor deposition (CVD) apparatus, evaporation (thermal, RF, laser, or electron beam) apparatus, reactive evaporation apparatus, sputtering (DC, RF, microwave and/or magnetron) apparatus, arc plasma deposition apparatus, reactive sputtering apparatus, electron beam physical vapor deposition (EF-PVD) apparatus, electroplating apparatus, ion plasma deposition (IPD) apparatus, low pressure plasma spray (LPPS) apparatus, plasma spray (e.g., air plasma spray (APS)) apparatus, high velocity oxy-fuel (HVOF) apparatus, vapor deposition apparatus, or cluster deposition apparatus.

56. The apparatus of claim 54, wherein said deposition means comprises:
a directed vapor deposition (DVD) apparatus.

57. A directed vapor deposition (DVD) apparatus for forming a thermal barrier coating system, the apparatus comprising:
a chamber, wherein said chamber has an operating pressure ranging from about 0.1 to about 32,350 Pa, wherein at least one substrate is presented in said chamber;
at least one evaporant source disposed in said chamber;
at least one carrier gas stream provided in said chamber; and
an energetic beam system providing at least one energetic beam,
said energetic beam:
impinging at least one said evaporant source with at least one said energetic beam in said chamber to generate a bond coat evaporated vapor flux, and
deflecting at least one of said generated bond coat evaporated vapor flux by at least one of said carrier gas stream, wherein said bond coat evaporated vapor flux at least partially coats at least one of said substrates to form said bond coat; and
said energetic beam:
impinging at least one of said evaporant source with at least one said energetic beam in said chamber to generate a thermal-insulating layer evaporated vapor flux, wherein said evaporant source for generating said thermal-insulating layer comprise at least one of zirconia, carbides, borides, and/or at least one refractory metal or combination thereof or any of their alloys, and
deflecting at least one of said thermal-insulating layer generated evaporated vapor flux by at least one of said carrier gas stream, wherein said thermal-insulating layer evaporated vapor flux at least partially coats at least one of said substrates to form said thermal-insulating layer on said bond coat comprising columnar grains; and
said energetic beam:
impinging at least one of insoluble source with at least one said energetic beam in said chamber to generate secondary grains in said thermal-insulating layer to provide gaps or structured porosity in said columnar grains.

58. A coating system on a substrate, the coating system comprising:
a bond coat in communication with at least a portion of said substrate, said bond coat produced by deposition technique; and
a thermal-insulating layer in communication with at least a portion of said bond coat, said thermal-insulating layer comprising at least one of zirconia, carbide, boride, refractory metal, zirconia alloy, carbide alloy, boride alloy, and/or refractory metal alloy, or any combination thereof.

59. The system of claim 58, wherein:
said refractory metal comprise at least one of Molydenum (Mo), Niobium (Nb), Tantalum (Ta), Titanium (Ti), or Tungsten (W), or any combination thereof, and
said refractory metal alloy comprise at least one of alloys of Mo, Nb, Ta, Ti or W, or any combination thereof.

60. The method of claim 58, wherein said carbide material comprise at least one of TiC, HfC, ZrC, TaC, W2C, SiC, alloys of TiC, HfC, ZrC, TiAl, TaC, W2C, SiC, or any combination thereof.

61. The system of claim 58, further comprising:
at least one recess in at least one of said substrate or said bond coat.

62. The system of claim 61, wherein said recess comprises a columnar gap inducing geometry.

63. The system of claim 61, wherein said recess comprises:
at least one of indentation, aperture, port, duct, groove, channel, dimple, bore, inlet, outlet, hole, conduit, perforation, channel, passage, pipe, tube, slot, flute, well, and/or tunnel, or any combination thereof.

64. The system of claim 58, wherein said thermal-insulating layer comprise plurality of columnar grains having an outer surface comprising gaps there between, wherein:
said gaps at the outer surface amounts to about ten percent or greater of the distance spanning across opposite-outside limits of two adjacent columns.

65. The system of claim 58, wherein said thermal-insulating layer comprise plurality of columnar grains having an outer surface comprising gaps there between, wherein:
said gaps at the outer surface amounts to about five percent or greater of the distance spanning across opposite-outside limits of two adjacent columns.

66. The system of claim 58, wherein said thermal-insulating layer is a three-dimensional truss structure.

67. The system of claim 58, wherein said thermal-insulating layer is a three-dimensional cellular structure.

68. The system of claim 58, wherein said thermal-insulating layer is a reticulated foam structure.

69. The system of claim 58, wherein said substrate is at least one of:
rocket engine component, space reentry vehicle component, scram jet component, hypersonic vehicle component, fusion reactor component, gas turbine engine component, diesel engine component, turbine blade, and airfoil.

70. The system of claim 58, wherein said deposition technique of said bond coat and thermal insulating layer is accomplished with a deposition method comprising:
at least one of directed vapor deposition (DVD), chemical vapor deposition (CVD), evaporation (thermal, RF, laser, or electron beam), reactive evaporation, sputtering (DC, RF, microwave and/or magnetron), arc plasma deposition, reactive sputtering, electron beam physical vapor deposition (EF-PVD), electroplating, ion plasma deposition (IPD), low pressure plasma spray (LPPS), plasma spray (e.g., air plasma spray (APS)), high velocity oxy-fuel (HVOF), vapor deposition, or cluster deposition.

71. The system of claim 58, wherein said deposition technique of said bond coat and thermal insulating layer is accomplished with a directed vapor deposition (DVD).
